(19) United States
(12) Patent Application Publication
(10) Pub. No.: US 2019/0032244 A1
(43) Pub. Date: Jan. 31, 2019

(54) CHEMICAL VAPOR DEPOSITION SYSTEM

(71) Applicant: HERMES-EPITEK CORPORATION, Taipei City (TW)

(72) Inventors: Po-Ching Lu, Taipei City (TW); Kuan-Ning Huang, New Taipei City (TW)

(21) Appl. No.: 16/040,364

(22) Filed: Jul. 19, 2018

(30) Foreign Application Priority Data
Jul. 28, 2017 (TW) 106125500

(51) Int. Cl. C30B 25/10; C23C 16/458; C23C 16/46; H01L 21/67; H01L 21/687

(52) U.S. Cl. CPC C30B 25/10; C23C 16/4583; H01L 21/68771; H01L 21/67248; C23C 16/46

(57) ABSTRACT

In accordance with an embodiment, a chemical vapor deposition system is provided with a susceptor, a plurality of wafer holders, and a processing gas. The susceptor carries the plurality of wafer holders with each bearing a wafer. The susceptor makes revolution around a central axis. The periphery of the wafer includes a chamfer, and each wafer holder includes a protrudent structure having a horizontal bottom surface and an inclined bearing surface to bear the chamfer of the wafer. The processing gas approaches a surface of the wafer and is heated to form a thin film to be deposited on the surface.

### CROSS-REFERENCE TO RELATED APPLICATIONS

The entire contents of Taiwan Patent Application No. 106125500, filed on Jul. 28, 2017, from which this application claims priority, are expressly incorporated herein by reference.

### BACKGROUND OF THE INVENTION

### 1. Field of the Invention

The present invention relates to a deposition system and more particularly relates to a gas vapor deposition system.

### 2. Description of Related Art

Metal-Organic Chemical Vapor Deposition (MOCVD) is a process to deposit a film on the surface of semiconductor wafer or other substrates. MOCVD employs a carrier gas to carry gaseous reactants or precursors into a reactor chamber loaded with wafers. A susceptor bears the wafers and uses a heating mechanism to heat the wafers as the gases approaches the substrates. As the temperature of the approaching gases is raised, one or more chemical reactions are triggered. The chemical reactions convert gaseous reactants into solid products to be deposited on the surfaces of the wafers.

U.S. Pat. No. 7,670,434 discloses a vapor phase growth apparatus, and FIG. 1 is a sectional view showing the disclosed vapor phase growth apparatus 1. As shown in FIG. 1, the vapor phase growth apparatus 1 includes a reactor 10, a wafer holder 11 serving as a wafer containing member on which wafers 13 are mounted, a susceptor 12 that holds the wafer holder 3, and a heater 14 provided below the susceptor 14, a rotation mechanism 15 which rotatably supports the wafer holder 11 and the susceptor 12, gas inlet pipes 16 for supplying raw material gas and carrier gas, and a gas exhaust pipe 17 to exhaust unreacted gases.

FIG. 2A is a top view of the wafer holder 11 in FIG. 1, and FIG. 2B is a cross-sectional view of FIG. 2A taken along line A-A.

The apparatus 1 and the wafer holder 11 shown in FIGS. 1, 2A, and 2B is a Face-Up chemical vapor apparatus. In the field, there is another configuration called “Face-Down chemical vapor deposition apparatus”. U.S. Pat. No. 9,617,636 discloses a system and method for controlling surface temperature of wafer and thin-film grown on the wafer. FIG. 3 is a partial cross-sectional schematic view showing the Face-Down chemical deposition system 2 of the system and method in that patent.

As shown in FIG. 3, the vapor deposition system 2 includes a susceptor 20 and a plurality of wafer holders 21. The susceptor 20 may have a plurality of, for example, five or six wafer holders 21 thereon. FIG. 1 merely shows an half of the deposition system, and the other half is symmetrically arranged at the other side of the axis 22. A susceptor driving system 23 is used to drive the susceptor 20 to rotate around the axis 22. Each wafer holder 21 carries a wafer 24 with a surface facing downward. A support plate 25 is arranged at a front of the wafer holder 16 and at a distance from the wafer 24, and a processing zone 26 is between the support plate 25 and the wafer holder 21. A processing gas 27 (e.g., carrier gas with reactant gases and/or precursor gases) pass through the processing zone 26, and some of which is heated to turn into solid products to be deposited on the surface of the wafer 24 and thus to form a thin-film on the surface of the wafer 24. The unreacted processing gas 26 will be discharged through the exit zone 28. In addition, a heater 29, such as an isothermal plate 29, is arranged at the rear of the wafer holder 21 for heating the wafer 24. A (air) gap 30 may be present between the isothermal plate 29 and the back side of the wafer 24. The temperature control system 35 includes front temperature control system 31 and rear temperature control system 32. The front temperature control system 31 includes temperature-measuring devices 31a/31b/31c to measure a front surface temperature of the wafer 24. The rear temperature control system 32 includes temperature-measuring devices 32a/32b/32c to measure a rear surface temperature of the isothermal plate 29.

As shown in FIG. 3, in the face down chemical deposition system, a portion of the surface of the wafer 24 is covered by the wafer holder 21, and the thin film cannot be deposited on the covered portion. This portion can be called “an ineffective region,” resulting in a reduced yield.

FIGS. 4 and 5 are photographs showing that the wafer 24 is covered by the wafer holder 21 of the conventional deposition system to form an ineffective region. FIG. 5 is a partial enlarged view of FIG. 4. As shown in FIG. 5, the width of the ineffective region of the wafer can reach 2000 μm.

In view of the above drawbacks, there is a need to design a wafer holder for a chemical vapor deposition system so as to reduce the ineffective region of the deposition and therefore to improve the yield.

### SUMMARY OF THE INVENTION

In one general aspect, the present invention relates to a chemical deposition system and its wafer holder.

According to an aspect of the present invention, a chemical vapor deposition system is provided with a susceptor, a plurality of wafer holders, a plurality of wafers, and a processing gas. The susceptor rotates about an axis. The wafer holders are located on the susceptor. One wafer is carried by one corresponded wafer holder and has an epitaxial surface, wherein a periphery of the wafer includes a chamfer, the wafer holder includes a protrudent structure extending toward the wafer, and the protrudent structure includes a horizontal bottom surface and an inclined bearing surface to bear the chamfer of the wafer. The processing gas approaches the epitaxial surface of the wafer and is heated to form a thin film deposited on the epitaxial surface.

In one embodiment, an included angle is between the horizontal bottom surface and the inclined bearing surface, and the included angle is equal to the angle of the chamfer.

In one embodiment, the inclined bearing surface is ring-shaped.

In one embodiment, the inclined bearing surface is located at or near a lower end an inner sidewall of the wafer holder.

In one embodiment, the chemical vapor deposition system is a face-down chemical vapor deposition system.

According to another aspect of the present invention, a chemical vapor deposition system is provided with a susceptor, a plurality of wafer holders, and a processing gas. The susceptor rotates about an axis. The wafer holders are located on the susceptor, with each wafer holder carrying a wafer having an epitaxial surface. In addition, each wafer holder includes a plurality of hook structures, and a tip of each hook structure has a contact to support the epitaxial surface. The processing gas approaches the epitaxial surface of the wafer and is heated to form a thin film deposited on the epitaxial surface.

In one embodiment, the contact has an arc configuration.

In one embodiment, each of the wafer holders supports the wafer with a plurality of linear contacts.

In one embodiment, the contact has a round configuration.

In one embodiment, each of the wafer holders supports the wafer with a plurality of point contacts.

### BRIEF DESCRIPTION OF THE DRAWINGS

FIG. 1 is a cross-sectional view showing a conventional face-up chemical vapor phase growth apparatus.

FIG. 2A is a top view showing the wafer holder of the vapor phase growth apparatus of FIG. 1.

FIG. 2B is a cross-sectional view taken along line A-A of FIG. 2A and showing the wafer holder of the vapor phase growth apparatus of FIG. 1.

FIG. 3 is a schematic diagram showing a conventional face-down vapor deposition apparatus.

FIG. 4 is a photograph showing an ineffective region of a wafer of a conventional chemical vapor deposition apparatus.

FIG. 5 is an enlarged photograph of FIG. 4 showing the ineffective region of a wafer of a conventional chemical vapor deposition apparatus.

FIG. 6A is a side view showing a wafer holder according to a first embodiment of the present invention.

FIG. 6B is a partial perspective sectional view showing the wafer holder according to the first embodiment of the present invention.

FIG. 7 is a photograph showing ineffective regions of a wafer carried by a wafer holder according to a first embodiment of the present invention.

FIG. 8A is a bottom perspective view of a wafer holder according to a second embodiment of the present invention.

FIG. 8B is a side view showing a wafer holder according to the second embodiment of the present invention.

FIG. 8C is a schematic top view showing a wafer holder and a wafer according to the second embodiment of the present invention.

FIG. 9 is a photograph showing ineffective regions of a wafer carried by a wafer holder according to the second embodiment of the present invention.

FIG. 10A is a side view showing a wafer holder according to a third embodiment of the present invention.

FIG. 10B is a schematic top view showing a wafer holder and a wafer according to the third embodiment of the present invention.

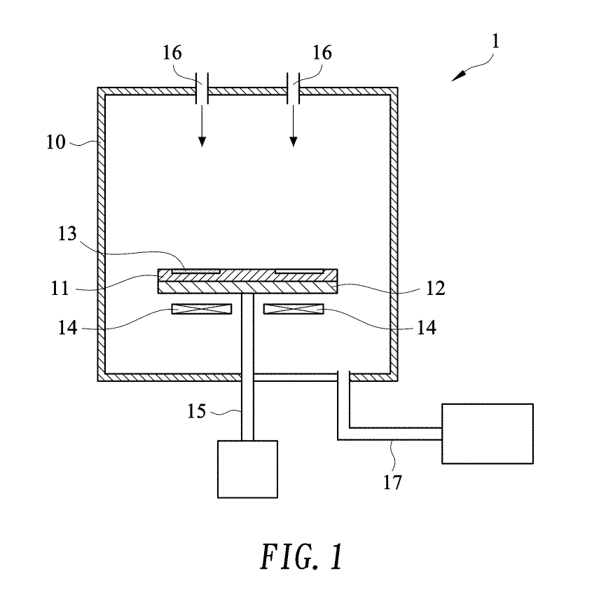

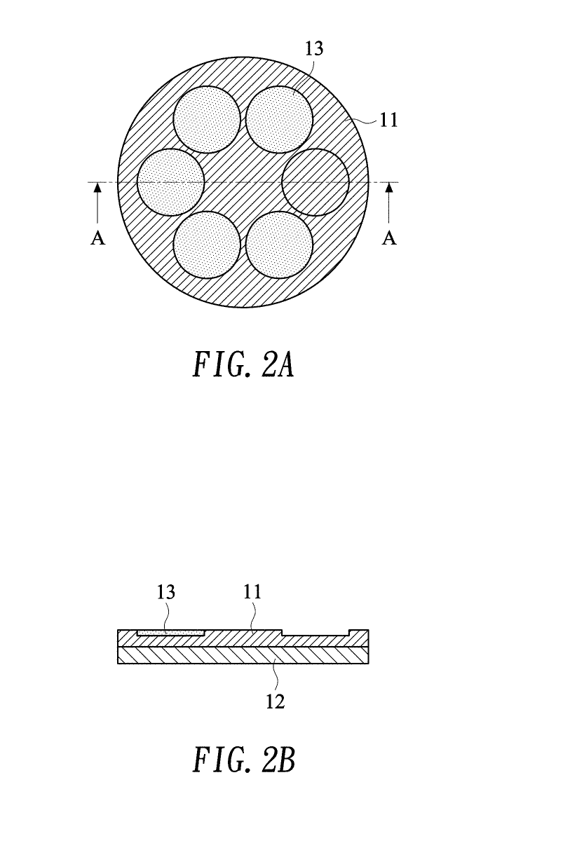

### DETAILED DESCRIPTION OF THE PREFERRED EMBODIMENT

Reference will now be made in detail to those specific embodiments of the invention. Examples of these embodiments are illustrated in accompanying drawings. While the invention will be described in conjunction with these specific embodiments, it will be understood that it is not intended to limit the invention to these embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known process operations and components are not described in detail in order not to unnecessarily obscure the present invention. While drawings are illustrated in detail, it is appreciated that the quantity of the disclosed components may be greater or less than that disclosed, except where expressly restricting the amount of the components. In addition, some of the disclosed components may not be drawn in scale, and some portion of the disclosed components may be magnified or simplified to stress the features of the invention. Wherever possible, the same or similar reference numbers are used in drawings and the description to refer to the same or like parts.

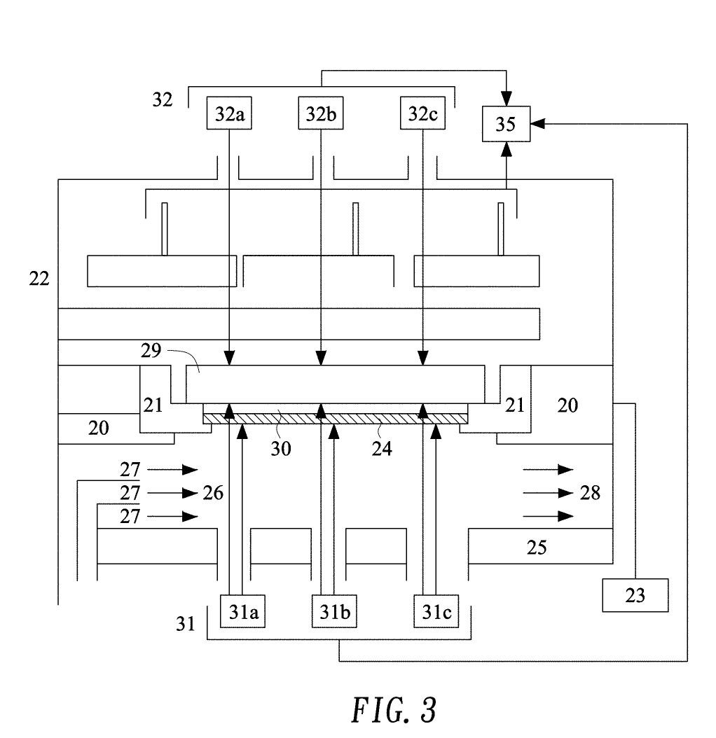

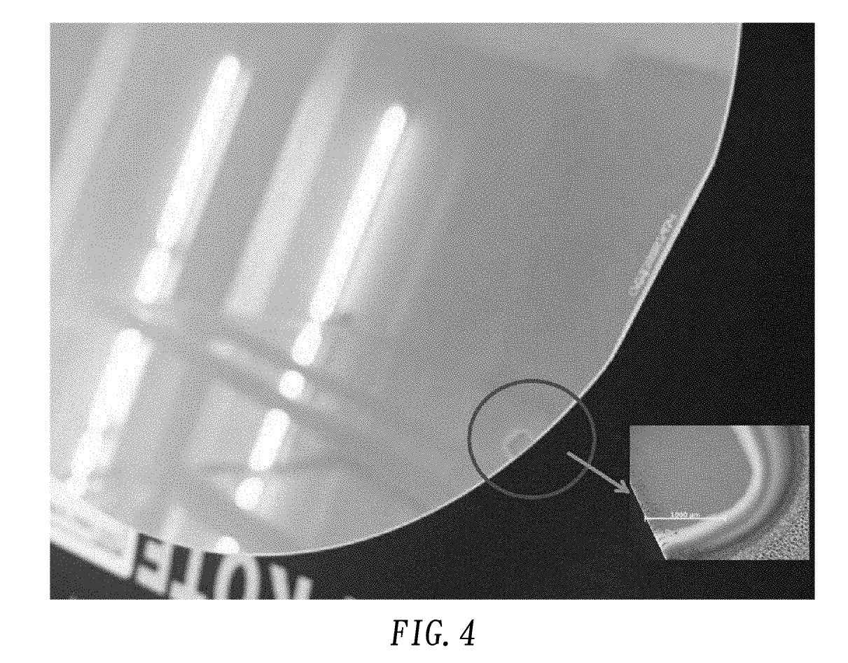

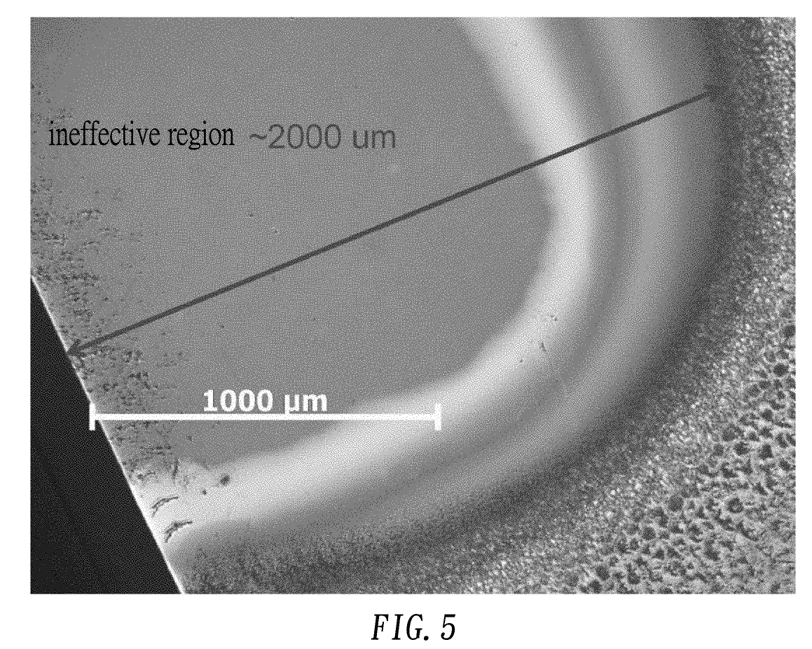

In the vapor deposition system of FIG. 3, because the plurality of wafer holders 21 are simultaneously carried by the susceptor 20 and both the susceptor 20 and the wafer holder 21 are rotated, the wafer 24 cannot be held in the exact same position during the deposition process. In addition, the wafer 24 may be made of variant materials, such as sapphire, silicon, plastics, etc., which have different coefficients of thermal expansion. As a result, the dimensions of different wafers are different after heating. All the above-mentioned factors increase the difficulty in designing the wafer holder 21.

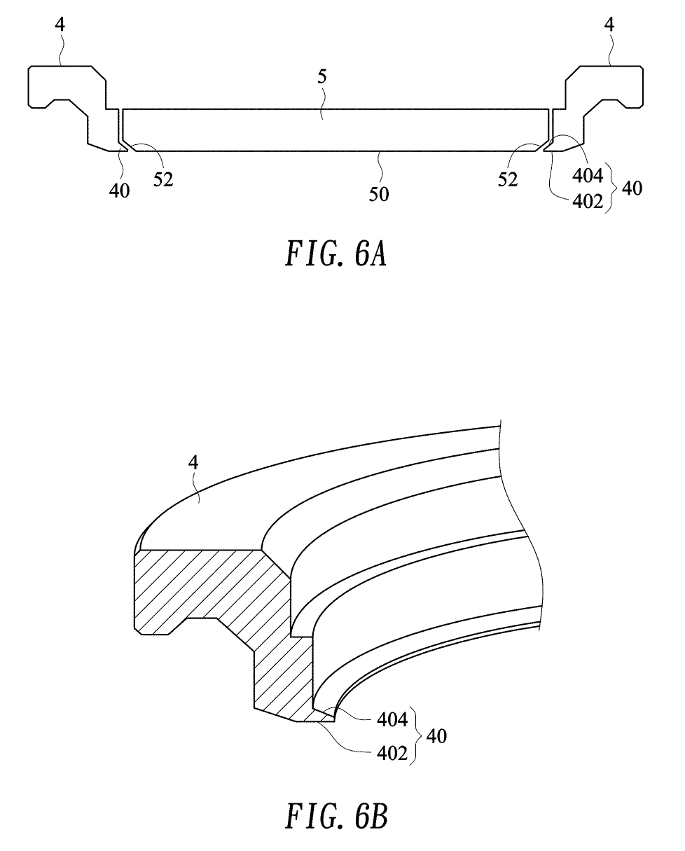

FIG. 6A is a side view and FIG. 6B is a partially perspective sectional view showing a wafer holder 4 according to an embodiment of the present invention. As shown in FIGS. 6A and 6B, the wafer holder 4 is preferably adapted to, but is not limited to, a face-down vapor deposition system, such as the vapor deposition system 2 illustrated in FIG. 3. In the present embodiment, the wafer 5 has a downward epitaxial surface 50 with a chamfer 52 at its periphery, and the wafer holder 4 has a protrudent structure 40 at its lower end or at a portion near the lower end of the inner side wall to extend toward the wafer 5. The protrudent structure 40 has a horizontal bottom surface 402 and an inclined bearing surface 404, and an inclined angle is between the horizontal bottom surface 402 and the inclined bearing surface 404. The inclined angle can match the angle of the chamfer 52 of the wafer. For example, the chamfer 52 of the wafer 5 is 45 degrees, and the inclined angle between the bottom surface 402 and the bearing surface 404 is 45 degrees, too. In another embodiment of the present invention, the chamfer 52 of the wafer is 30 degrees, and the inclined angle between the bottom surface 402 and the bearing surface 404 is 30 degrees, too.

As shown in FIG. 6A and FIG. 6B, in the present embodiment, the inclined bearing surface 404 of the wafer holder 4 supports the chamfer 52 of the wafer 5, so that the epitaxial surface 50 of the wafer 5 can be utilized to the maximum extent. As shown in FIGS. 6A and 6B, in the present embodiment, the bearing surface 404 may have a ring configuration. Ideally, the chamfer 52 of the wafer 5 is completely supported by the inclined bearing surface 404 of the wafer holder 4, so that all the epitaxial surface 50 can be deposited with thin films and no ineffective regions are generated. However, actually, as described above, because the plurality of wafer holders 4 are simultaneously carried by the susceptor 20 (FIG. 3) and both the susceptor 20 and the wafer holders 4 are rotated and different wafers 5 have different coefficients of thermal expansion, the wafer 5 cannot be held in the exact same position during the deposition process. That is, the center of the wafer 5 may not be able to fall on the center of the wafer holder 4 during depositing a thin film. Sometimes the center of the wafer 5 may slightly deviate from the center of the wafer holder 4. In such a case, it may cause that a portion of the epitaxy surface 50 in the periphery of the wafer 5 still has a small ineffective region.

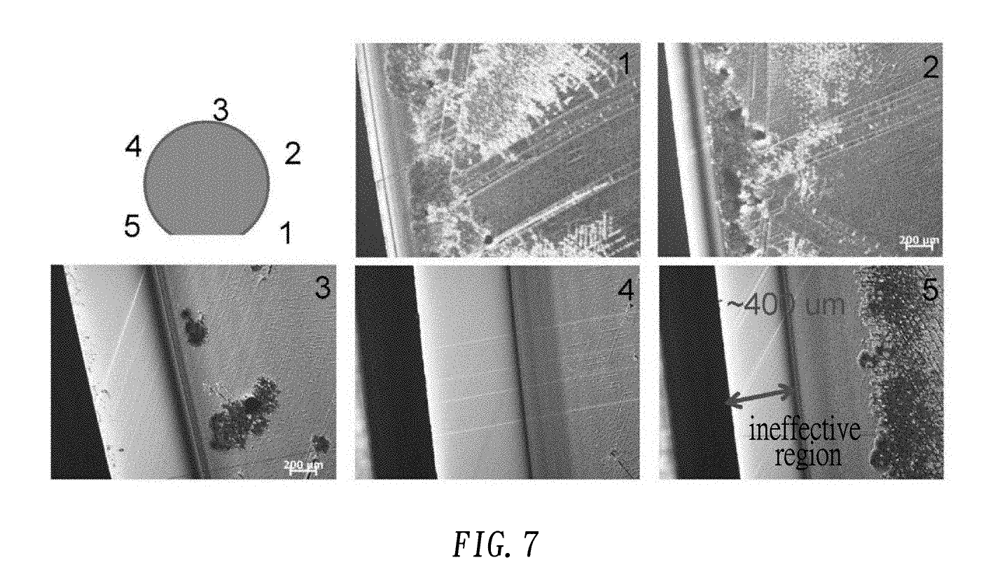

FIG. 7 is a photograph showing a wafer 5 carried by the wafer holder 4 of FIGS. 6A and 6B after a thin film is deposited thereon. In order to evaluate the periphery of the epitaxial surface 50, five areas of periphery of the wafer are selected, such as the areas labeled 1, 2, 3, 4, and 5 for evaluation. As shown in FIG. 7, the wafer has some very slight ineffective regions in areas labeled 1, 2, and 3. In the area labeled 4, no ineffective regions appear. In the area labeled 5, a slightly obvious ineffective region with about 400 μm in width is observed. By contrast, conventional wafer holder has an ineffective area with 2000 μm in width. According to the results, the wafer holder 4 of this embodiment has greatly reduced the ineffective region.

In addition, as shown in FIGS. 6A and 6B, the wafer holder 4 supports the chamfer 52 of the wafer 5 with the inclined bearing surface 404, so that the structure of wafer holder 4 does not affect the processing gas of the processing zone. The gas flow pattern of the processing gas can be maintained as laminar flow. According to fluid mechanics, as the Reynolds number is small, the viscous forces of the fluid dominate the inertial forces, resulting in stable laminar flow with no disruption between layers. The laminar flow is necessary within the reactor for completing reactions, reducing defects, and prompting the uniformity of the deposition.

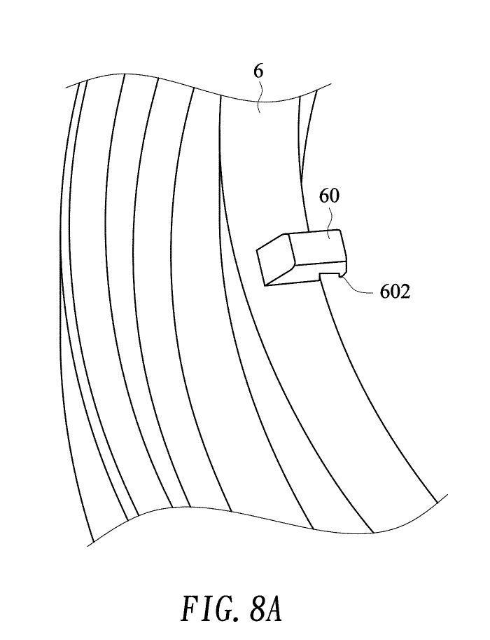

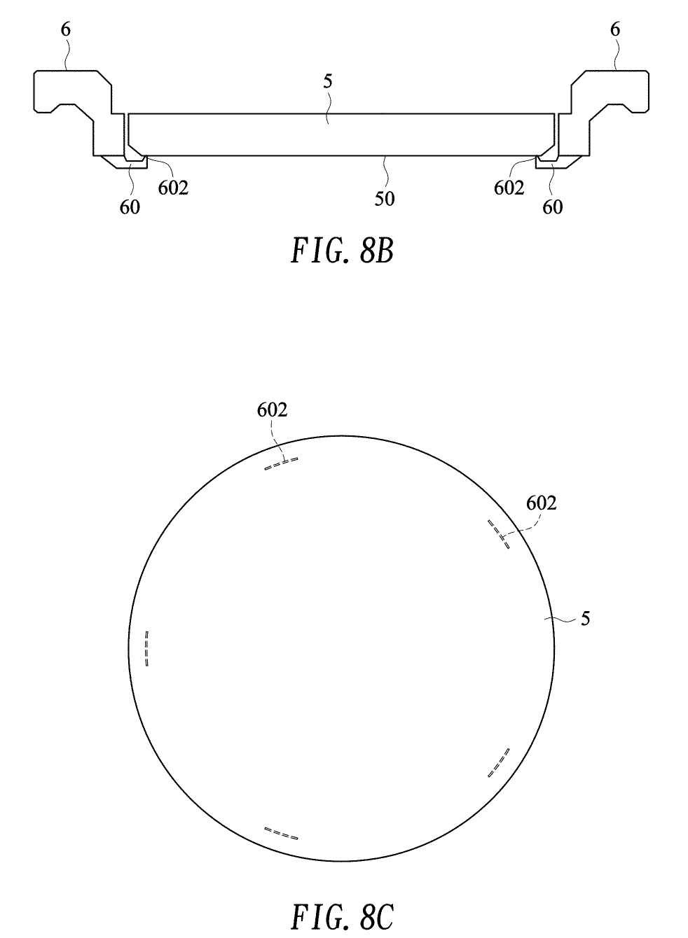

FIG. 8A is a perspective view taken from bottom, FIG. 8B is a side view, and FIG. 8C is a schematic top view showing a wafer holder 6 and a wafer 5 according to another embodiment of the present invention. As shown in FIGS. 8A-8C, the wafer holder 6 is preferably applied to, but is not limited to, a face-down vapor deposition system, such as the vapor deposition system 2 illustrated in FIG. 3. In this embodiment, the wafer 5 has a downward epitaxial surface 50 on which one or more thin films can be deposited after reactions of the processing gas occur. A plurality of hook structures 60 are disposed below each wafer holder 6, and the tip of each of the hook structures 60 has a contact 602 to support the epitaxial surface 50 of the wafer 5. In this embodiment, there are five hook structures 60 below each wafer holder 6, but the number of hook structures is not limited to five. FIG. 8C is a schematic top view of the wafer 5. As shown in FIG. 8C, the contact 602 at the tip of the hook structure 60 of the wafer holder 6 has an arc configuration.

As shown in FIGS. 8A to 8C, in an ideal case, the wafer holder 6 has a plurality of, for example, five, hook structures 60 to contact the epitaxial surface 50 of the wafer 5, so that the wafer 5 can be carried by the wafer holder 6, and the contact area between the wafer holder 6 and the epitaxial surface 50 of the wafer 5 is greatly reduced. In addition, in this embodiment, the contact 602 of the hook structure 60 of the wafer holder 6 has an arc configuration so that the contact area between the epitaxial surface 50 of the wafer 5 and the wafer holder 6 is only five arcs (the contact can be regarded as linear contact), which can greatly reduce the ineffective region.

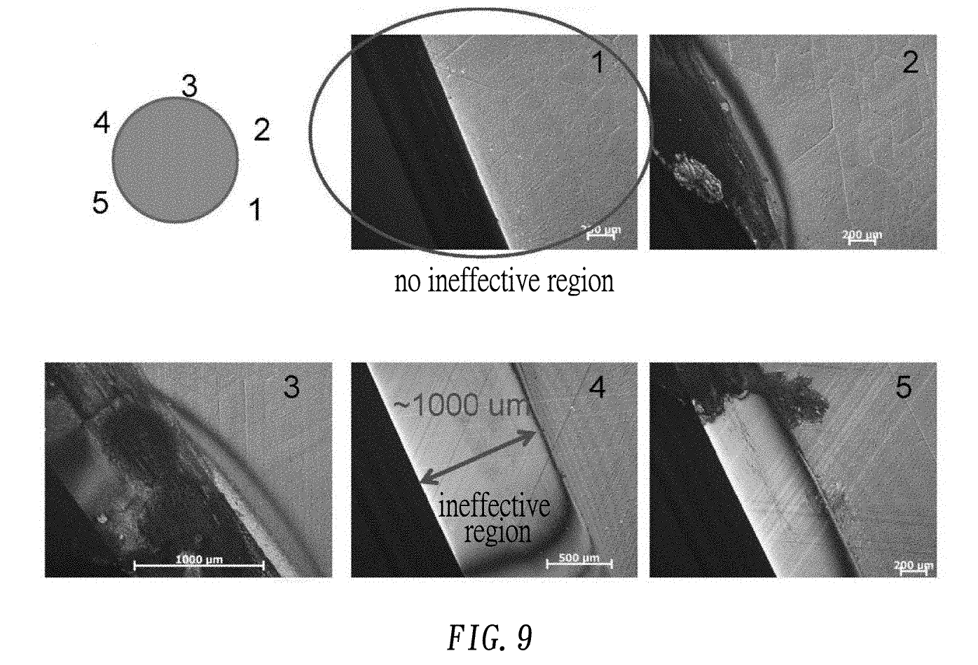

FIG. 9 is a photograph showing the wafer 5 carried by the wafer holder 6 of FIGS. 8A-6C after a thin film is deposited thereon. In order to evaluate the periphery of the epitaxial surface 50, five areas of periphery of the wafer are selected, such as the areas labeled 1, 2, 3, 4, and 5 for evaluation. As shown in FIG. 9, the wafer has some very slight ineffective regions with about 200-350 μm in width observed in areas labeled 1, 2, and 5. In the areas labeled 3 and 4, a little obvious ineffective area with about 1000 μm in width is observed. By contrast, the conventional wafer holder has an ineffective region with 2000 μm in width. According to the results, the wafer holder 6 of this embodiment has greatly reduced the ineffective region. In addition, the experiments also confirm that the structure of the wafer holder 6 does not affect the flow pattern of the processing gas, which can be maintained as a laminar flow.

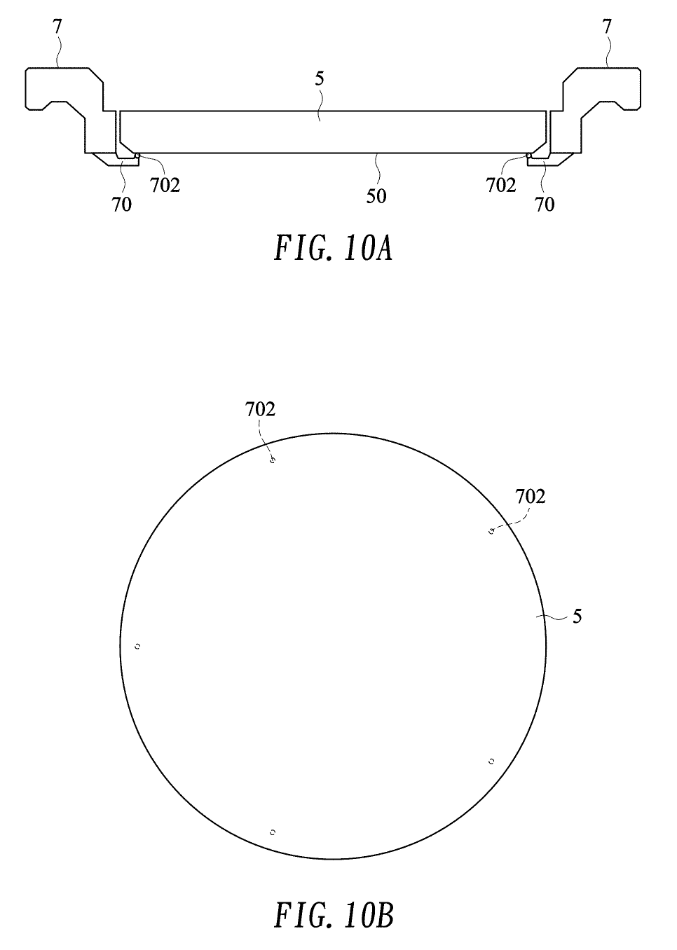

FIG. 10A is a side view, and FIG. 10B is a schematic top view showing a wafer holder 7 and a wafer 5 according to another embodiment of the present invention. A plurality of hook structures 70 are disposed below each wafer holder 7, and the tip of each of the hook structures 70 has a contact 702 to support the epitaxial surface 50 of the wafer 5. In this embodiment, there are five hook structures 70 below each wafer holder 7, but the number of hook structures 70 is not limited to five. FIG. 10B is a schematic top view of the wafer 5. As shown in FIG. 10B, the contact 702 at the tip of the hook structure 70 of the wafer holder 7 has an round configuration.

As shown in FIGS. 10A and 10B, ideally, the wafer holder 7 has a plurality of, for example, five, hook structures 70 to contact the epitaxial surface 50 of the wafer 5, so that the wafer 5 can be carried by the wafer holder 7, and the contact area between the wafer holder 7 and the epitaxial surface 50 of the wafer 5 is greatly reduced. In addition, in this embodiment, the contact 702 of the hook structure 70 of the wafer holder 7 has an around configuration so that the contact area between the epitaxial surface 50 of the wafer 5 and the wafer holder 7 is only five points (the contact can be regarded as point contact), which can greatly reduce the ineffective region.

According to the wafer holder provided by embodiments of the present invention, the ineffective regions of the wafer can be greatly reduced during the deposition, so as to increase the yield. In addition, the structure of the wafer holder does not affect the flow pattern of the processing gas. The gas flow pattern can maintain as laminar flow and thereby promote the epitaxial uniformity.

The intent accompanying this disclosure is to have each/all embodiments construed in conjunction with the knowledge of one skilled in the art to cover all modifications, variations, combinations, permutations, omissions, substitutions, alternatives, and equivalents of the embodiments, to the extent not mutually exclusive, as may fall within the spirit and scope of the invention. Corresponding or related structure and methods disclosed or referenced herein, and/or in any and all co-pending, abandoned or patented application(s) by any of the named inventor(s) or assignee(s) of this application and invention, are incorporated herein by reference in their entireties, wherein such incorporation includes corresponding or related structure (and modifications thereof) which may be, in whole or in part, (i) operable and/or constructed with, (ii) modified by one skilled in the art to be operable and/or constructed with, and/or (iii) implemented/made/used with or in combination with, any part(s) of the present invention according to this disclosure, that of the application and references cited therein, and the knowledge and judgment of one skilled in the art.

Conditional language, such as, among others, “can,” “could,” “might,” or “may,” unless specifically stated otherwise, or otherwise understood within the context as used, is generally intended to convey that embodiments include, and in other interpretations do not include, certain features, elements and/or steps. Thus, such conditional language is not generally intended to imply that features, elements and/or steps are in any way required for one or more embodiments, or interpretations thereof, or that one or more embodiments necessarily include logic for deciding, with or without user input or prompting, whether these features, elements and/or steps are included or are to be performed in any particular embodiment.

All of the contents of the preceding documents are incorporated herein by reference in their entireties. Although the disclosure herein refers to certain illustrated embodiments, it is to be understood that these embodiments have been presented by way of example rather than limitation. For example, any of the particulars or features set out or referenced herein, or other features, including method steps and techniques, may be used with any other structure(s) and process described or referenced herein, in whole or in part, in any combination or permutation as a non-equivalent, separate, non-interchangeable aspect of this invention. Corresponding or related structure and methods specifically contemplated and disclosed herein as part of this invention, to the extent not mutually inconsistent as will be apparent from the context, this specification, and the knowledge of one skilled in the art, including, modifications thereto, which may be, in whole or in part, (i) operable and/or constructed with, (ii) modified by one skilled in the art to be operable and/or constructed with, and/or (iii) implemented/made/used with or in combination with, any parts of the present invention according to this disclosure, include: (I) any one or more parts of the above disclosed or referenced structure and methods and/or (II) subject matter of any one or more of the inventive concepts set forth herein and parts thereof, in any permutation and/or combination, include the subject matter of any one or more of the mentioned features and aspects, in any permutation and/or combination.

What is claimed is:

1. A chemical vapor deposition system, comprising:
a susceptor rotating about an axis;
a plurality of wafer holders located on the susceptor;
a wafer being carried by each of the plurality of wafer holder and having an epitaxial surface, wherein a periphery of the wafer includes a chamfer, each wafer holder includes a protrudent structure extending toward the wafer, and the protrudent structure includes a horizontal bottom surface and an inclined bearing surface to bear the chamfer of the wafer; and
a processing gas approaching the epitaxial surface of the wafer and being heated to form a thin film deposited on the epitaxial surface.

2. The chemical vapor deposition system of claim 1, wherein an included angle is between the horizontal bottom surface and the inclined bearing surface, and the included angle is equal to the angle of the chamfer.

3. The chemical vapor deposition system of claim 1, wherein the inclined bearing surface is ring-shaped.

4. The chemical vapor deposition system of claim 1, wherein the inclined bearing surface is located at or near a lower end an inner sidewall of the wafer holder.

5. The chemical vapor deposition system of claim 1, wherein the chemical vapor deposition system is a face-down chemical vapor deposition system.

6. A chemical vapor deposition system, comprising:
a susceptor rotating about an axis;
a plurality of wafer holders located on the susceptor, each wafer holder carrying a wafer having an epitaxial surface, each wafer holder having a plurality of hook structures, a tip of each hook structure having a contact to support the epitaxial surface;
a processing gas approaching the epitaxial surface of the wafer and being heated to form a thin film deposited on the epitaxial surface.

7. The chemical vapor deposition system of claim 6, wherein the contact has an arc configuration.

8. The chemical vapor deposition system of claim 6, wherein each of the wafer holders supports the wafer with a plurality of linear contacts.

9. The chemical vapor deposition system of claim 6, wherein the contact has a round configuration.

10. The chemical vapor deposition system of claim 6, wherein each of the wafer holders supports the wafer with a plurality of point contacts.

11. The chemical vapor deposition system of claim 6, wherein the hook structure is located below the wafer holder.

12. The chemical vapor deposition system of claim 6, wherein the chemical vapor deposition system is a face-down chemical vapor deposition system.
